(19) United States
(12) Patent Application Publication
(10) Pub. No.: US 2023/0407171 A1
(43) Pub. Date: Dec. 21, 2023

(54) PHOSPHOR POWDER, LIGHT-EMITTING DEVICE, IMAGE DISPLAY DEVICE, AND ILLUMINATION DEVICE

(71) Applicant: DENKA COMPANY LIMITED, Tokyo (JP)

(72) Inventor: Hideyuki EMOTO, Tokyo (JP)

(73) Assignee: DENKA COMPANY LIMITED, Tokyo (JP)

(21) Appl. No.: 18/035,435

(22) PCT Filed: Nov. 4, 2021
(86) PCT No.: PCT/JP2021/040565

§ 371 Date: May 4, 2023

(30) Foreign Application Priority Data
Nov. 13, 2020 (JP) 2020-189203

(51) Int. Cl. C09K 11/77; C09K 11/55; C09K 11/08

(52) U.S. Cl. CPC C09K 11/77217; C09K 11/0883; C09K 11/55; C09K 11/77216

(57) ABSTRACT

A phosphor powder which is represented by a general formula Mₓ(Si, Al)₂(N, O)_{3±y} (where M is Li and one or more alkaline earth metal elements and 0.52≤x≤0.9 and 0.06≤y≤0.36 are satisfied) and in which a part of M is substituted with a Ce element, in which the phosphor powder includes phosphor particles in which a Si/Al atomic ratio is equal to or more than 1.5 and equal to or less than 6, an O/N atomic ratio is equal to or more than 0 and equal to or less than 0.1, 5 to 50 mol % of M is Li, and 0.5 to 10 mol % of M is Ce, and a diffuse reflectance X1 with respect to light having a wavelength of 700 nm is equal to or more than 88% and equal to or less than 99.9%.

### TECHNICAL FIELD

The present invention relates to a phosphor powder, a light-emitting device, an image display device, and an illumination device.

### BACKGROUND ART

Phosphors are commonly used to manufacture white light emitting diodes (LEDs). That is, a phosphor is used as a wavelength conversion material for obtaining white light from blue light emitted from a blue LED.

With the spread of white LEDs for illumination and studies regarding application of the white LEDs to image display devices, phosphors capable of converting blue light into light having longer wavelengths are continuously being developed.

An aspect of improving a phosphor is to modify a chemical composition of the phosphor.

For example, Patent Document 1 discloses a phosphor which is represented by a general formula Mₓ(Si, Al)₂(N, O)_{3±y} (where M is Li and one or more alkaline earth metal elements and 0.52×0.9 and 0.23 are satisfied) and in which a part of M is substituted with a Ce element, in which the phosphor powder includes phosphor particles in which a Si/Al atomic ratio is equal to or more than 1.5 and equal to or less than 6, an O/N atomic ratio is equal to or more than 0 and equal to or less than 0.1, 5 to 50 mol % of M is Li, and to 10 mol % of M is Ce.

### RELATED DOCUMENT

### Patent Document

[Patent Document 1] Japanese Patent No. 5969391

### SUMMARY OF THE INVENTION

### Technical Problem

As a finding of the present invention, a phosphor disclosed in Patent Document 1 has room for improvement in terms of conversion efficiency of blue light, specifically, in terms of increasing internal quantum efficiency.

The present inventors herein conducted studies to provide a phosphor powder having high internal quantum efficiency and improved conversion efficiency of blue light, as an object.

### Solution to Problem

The present inventors completed the invention provided below as a result of the studies.

According to the present invention, there is provided

a phosphor powder including phosphor particles of a phosphor which is represented by a general formula Mₓ(Si, Al)₂(N, O)_{3±y} (where M is Li and one or more alkaline earth metal elements and 0.52≤x≤0.9 and 0.06≤y≤0.36 are satisfied) and in which a part of M is substituted with a Ce element, in which the phosphor powder includes phosphor particles in which a Si/Al atomic ratio is equal to or more than 1.5 and equal to or less than 6, an O/N atomic ratio is equal to or more than 0 and equal to or less than 0.1, 5 to 50 mol % of M is Li, and 0.5 to 10 mol % of M is Ce, and a diffuse reflectance X1 with respect to light having a wavelength of 700 nm is equal to or more than 88% and equal to or less than 99.9%.

In addition, according to the present invention, there is provided a light-emitting device including the phosphor powder described above and a light emitting source.

In addition, according to the present invention, there is provided an image display device including the light-emitting device described above.

In addition, according to the present invention, there is provided an illumination device including the light-emitting device described above.

### Advantageous Effects of Invention

The phosphor powder of the present invention has high internal quantum efficiency and excellent conversion efficiency of blue light.

### BRIEF DESCRIPTION OF THE DRAWINGS

FIG. 1 is a schematic cross-sectional view showing an example of a structure of a light-emitting device.

FIG. 2 is an XRD pattern obtained by powder X-ray diffraction (XRD) measurement of a phosphor of Example 1.

### DESCRIPTION OF EMBODIMENTS

Hereinafter, an embodiment of the present invention will be described in detail while referring to drawings.

In the drawings, similar components are designated by the same reference numerals, and the description thereof will not be repeated.

The drawings are for explanation purposes only. A shape or a dimensional ratio of each member in the drawing does not necessarily correspond to an actual article.

In the present specification, the notation “X to Y” in the description of the numerical range indicates X or more and Y or less unless otherwise specified. For example, “1 to 5% by mass” means “equal to or more than 1% by mass and equal to or less than 5% by mass”.

<Phosphor Powder>

A phosphor powder of the present embodiment includes phosphor particles represented by a general formula Mₓ(Si, Al)₂(N, O)_{3±y}. In this general formula, M represents Li and one or more alkaline earth metal elements, and 0.52≤x≤0.9 and 0.06≤y≤0.36 are satisfied. In addition, a part of M is substituted with Ce element, the Si/Al atomic ratio is 1.5 or more and 6 or less, the O/N atomic ratio is 0 or more and 0.1 or less, and 5 to 50 mol % of M is Li and 0.5 to 10 mol % of M is Ce.

In addition, a diffuse reflectance X1 of the phosphor powder of the present embodiment with respect to light having a wavelength of 700 nm is equal to or more than 88% and equal to or less than 99.9%.

The phosphor powder of the present embodiment differs from the phosphor disclosed in Patent Document 1 at least in that X1 is equal to or more than 88% and equal to or less than 99.9%. The phosphor powder of the present embodiment efficiently converts blue light into light having a long wavelength, in terms of internal quantum efficiency, for example, compared to the phosphor disclosed in Patent Document 1.

Absorption of a phosphor includes light absorption accompanied by electronic transition of luminescence center ions, and light absorption unrelated to fluorescence emission derived from impurities, crystal defects of host materials, and the like. The light absorption in a case where the phosphor, which emits visible light, is irradiated with light in a near-infrared region, for example, having a wavelength of 700 nm, does not relate to the fluorescence emission and serves as an index for deterioration of fluorescence properties.

In order to quantitatively evaluate the effect of the light absorption described above, the present inventors newly produced various phosphors represented by a general formula Mₓ(Si, Al)₂(N, O)_{3±y}, as a trial, and measured the diffuse reflectance. As a result, it was found that the internal quantum efficiency tends to increase, in a case where the diffuse reflectance X1 at a wavelength of 700 nm is large. Based on this finding, the present inventors newly produced a phosphor powder including a phosphor represented by the general formula Mₓ(Si, Al)₂(N, O)_{3±y}, and having X1 equal to or more than 88% and equal to or less than 99.9%. The present inventors have succeeded in increasing the internal quantum efficiency of the phosphor powder.

The phosphor powder of the present embodiment can be produced by selecting suitable production method production conditions, in addition to usage of suitable materials. The “suitable production method production conditions” is, for example, one or two or more of (i) performing an acid treatment on the phosphor powder under specific conditions, (ii) performing a suitable classification treatment (for example, sedimentation classification) on the phosphor powder, (iii) performing a pulverization method of the phosphor powder, and the like. The production method production conditions will be described later in more detail.

The description of the phosphor powder of the present embodiment will be continued.

(Crystal Structure, Chemical Composition, and the like) A framework structure of a phosphor crystal is composed of (Si, Al)—(N, O) 4 regular tetrahedrons bonded together, and an M element is located in the interstices. A composition of the general formula described above is satisfied in a wide range in which electrical neutrality is maintained by all the parameters of a valence and an amount of the M element, the Si/Al ratio, and the N/O ratio. As a representative phosphor represented by the general formula described above, there is CaAlSiN₃ where the M element is Ca, x=1, Si/Al=1, and O/N=0. When a part of Ca in CaAlSiN₃ is substituted with Eu, it becomes a red phosphor, and when a part thereof is substituted with Ce, it becomes a yellow-orange phosphor.

The crystal structure of the phosphor particles included in the phosphor powder of the present embodiment is usually based on CaAlSiN₃ crystals. One of features of the phosphor particles is that constituent elements and a composition are greatly changed so that an extremely high luminous efficiency can be obtained even with Ce activation.

In the general formula described above, the M element is a combination of a Li element and an alkaline earth metal element, and a part thereof is substituted with a Ce element serving as a luminescence center. By using the Li element, an average valence of the M element can be widely controlled by combining with a divalent alkaline earth element and a trivalent Ce element. In addition, since an ionic radius of Li⁺ is extremely small, a crystal size can be changed greatly depending on the amount thereof, and various fluorescence emissions can be obtained.

A coefficient x of the M element in the general formula described above is equal to or more than 0.52 and equal to or less than 0.9, preferably equal to or more than 0.6 and equal to or less than 0.9, and more preferably equal to or more than 0.7 and equal to or less than 0.9. When the coefficient x exceeds 0.9, that is, when it approaches the CaAlSiN₃ crystal, the fluorescence intensity tends to decrease. When the coefficient x is smaller than 0.52, a large amount of a heterogeneous phase other than the desired crystal phase is generated, and thus, the fluorescence intensity tends to significantly decrease.

In the present embodiment, when the electrical neutrality is maintained by the average valence or the amount of the M element, the Si/Al ratio, and the O/N ratio and there is no defects or the like in a single crystal, y=0. However, when considering the composition of the entire phosphor, a secondary crystal phase or an amorphous phase exists, and even when considering the crystal itself, a charge balance may be lost due to crystal defects. In the present embodiment, from a viewpoint of increasing the fluorescence intensity, y is preferably equal to or more than 0.06 and equal to or less than more preferably equal to or more than 0.1 and equal to or less than 0.35, and even more preferably equal to or more than 0.06 and equal to or less than 0.23.

In the present embodiment, the O/N atomic ratio (a molar ratio) is equal to or more than 0 and equal to or less than 0.1, preferably equal to or more than 0.01 and equal to or less than 0.08, and more preferably equal to or more than 0.02 and equal to or less than 0.07. When the O/N atomic ratio is too large, the amount of the heterogeneous phases generated increases, the luminous efficiency decreases, a covalent bonding property of the crystal tends to decrease, and a deterioration of a temperature property (a decrease in luminance at a high temperature) tends to be caused.

The Si/Al atomic ratio (the molar ratio) is usually inevitably determined when the average valence or the amount of the M element and the O/N atomic ratio are set in predetermined ranges. The Si/Al atomic ratio is equal to or more than 1.5 and equal to or less than 6, preferably equal to or more than 2 and equal to or less than 4, and more preferably equal to or more than 2.5 and equal to or less than 4.

A Li content in the phosphor particles is 5 to 50 mol %, preferably to 45 mol %, and more preferably 25 to 45 mol % of the M element. An effect of Li is likely to be exhibited, when the Li content is equal to or more than 5 mol %, but, if the Li content exceeds 50 mol %, the desired crystal structure of the phosphor cannot be maintained, the heterogeneous phases are generated, and the luminous efficiency is likely to decrease.

Just to be sure, the “Li content” is the Li content in the finally obtained phosphor powder, not the amount based on a raw material mixture. The Li compound used as a raw material has a high vapor pressure and is easily volatilized, and a considerable amount volatilizes when an attempt is made to synthesize a nitride oxynitride at a high temperature. That is, the amount of Li based on the raw material mixture is largely different from the content in the final product, and thus, does not mean the Li content in the phosphor.

When the content of Ce, which is the luminescence center of the phosphor particles, is too small, the contribution to the fluorescence emission tends to decrease. When the content thereof is too great, concentration quenching of the phosphor due to energy transfer between Ce³⁺ tends to occur. Therefore, the content of Ce is 0.5 to 10 mol % and preferably 0.5 to 5 mol % of the M element.

The alkaline earth metal element used as the M element in the general formula described above may be any element, but, in a case where Ca is used, a high fluorescence intensity is obtained and the crystal structure is stabilized in a wide composition range. Therefore, the M element preferably contains Ca. The M element may be a combination of a plurality of alkaline earth metal elements, and for example, a part of the Ca element may be substituted with a Sr element.

The crystal structure of the phosphor particles is orthorhombic, and may have the same structure as the CaAlSiN₃ crystal described above. Lattice constants of the CaAlSiN₃ crystal are, as an example, a=0.98007 nm, b=0.56497 nm and c=0.50627 nm. In the present embodiment, the lattice constants are usually a=0.935 to 0.965 nm, b=0.550 to 0.570 nm, and c=0.480 to 0.500 nm, and all of the values are small values compared to the CaAlSiN₃ crystal. The ranges of the lattice constants reflect the constituent elements and the composition described above.

A crystal phase present in the phosphor particles is preferably the single phase described above. However, the phosphor particles may include a heterogeneous phase as long as the fluorescence properties are not significantly affected. Examples of the heterogeneous phase having a low effect on the fluorescence properties in a case of blue light excitation are α-SiAlON, AIN, LiSi₂N₃, LiAlSi₂N₄, and the like. The amount of the heterogeneous phase is preferably an amount such that a diffraction line intensity of other crystal phases with respect to a strongest diffraction line intensity of the crystal phase described above is equal to or less than 40% when evaluated by a powder X-ray diffraction method.

The phosphor powder of the present embodiment is excited by light having a wide wavelength range from ultraviolet to visible light. For example, in a case where blue light having a wavelength of 455 nm is emitted, broad fluorescence emission with a half width of the fluorescence spectrum equal to or more than 125 nm may be exhibited with orange light having a peak wavelength of 570 to 610 nm. Such a phosphor powder is suitable as a phosphor for wide-range light-emitting devices. In addition, the phosphor powder of the present embodiment has excellent heat resistance and chemical stability and a property, in which a thermal quenching is small, in the same manner as a nitride oxynitride-based phosphor of the related art represented by CaAlSiN₃. Such properties are particularly suitable for applications requiring durability.

(Diffuse Reflectance)

As described above, a diffuse reflectance X1 of the phosphor powder of the present embodiment with respect to light having a wavelength of 700 nm is equal to or more than 88% and equal to or less than 99.9%. X1 is preferably equal to or more than 90% and equal to or less than 99.9%, more preferably equal to or more than 92% and equal to or less than 99.9%, and particularly preferably equal to or more than 95% and equal to or less than 99.9%.

From another viewpoint, a diffuse reflectance X2 of the phosphor powder of the present embodiment with respect to light having a fluorescence peak wavelength is preferably equal to or more than 85% and equal to or less than 95% and more preferably equal to or more than 85.5% and equal to or less than 92%. When X2 is in such a numerical range, a luminous intensity tends to increase. When the phosphor is irradiated with the light having the fluorescence peak wavelength, not only non-radiative absorption due to impurities, crystal defects, or the like, but also absorption accompanied by electronic transition of the emission center ion occurs. Therefore, X2 is smaller than X1. However, the light absorption near the peak wavelength can be an index for re-excitation emission that causes a decrease in efficiency. In other words, a suitably large value of the X2 means that the contribution of re-excitation emission is small, and it is considered that the suitably large value of the X2 further improves the fluorescence properties.

From another viewpoint, a difference between X2 and X1 (X2-X1) is preferably equal to or more than 4% and equal to or less than 8%, more preferably equal to or more than 4% and equal to or less than 7%, and particularly preferably equal to or more than 4% and equal to or less than 6%. Although the details are not clear, it is considered that a value of X2-X1 which is equal to or more than 4% and equal to or less than 8% means that excellent balance is realized between the improvement of the fluorescence properties due to an increase in an absorption rate in a case where blue light is excited and the deterioration in fluorescence properties due to re-excitation emission, and thus, means that the properties of the phosphor are further improved.

(Particle Size Distribution)

By suitably designing a particle size distribution of the phosphor powder of the present embodiment, quantum efficiency may be further increased or the balance of various performances may be improved.

Specifically, a volume-based cumulative 50% particle size D50 (a so-called median size) of the phosphor powder of the present embodiment measured by a laser diffraction scattering method is preferably equal to or more than 8 μm and equal to or less than 25 μm, more preferably equal to or more than 10 μm and equal to or less than 20 μm, and more preferably equal to or more than 12 μm and equal to or less than 20 μm.

From another viewpoint, a volume-based cumulative 10% particle size D10 of the phosphor powder of the present embodiment measured by the laser diffraction scattering method is preferably equal to or more than 2 μm and equal to or less than 15 μm and more preferably equal to or more than 5 μm and equal to or less than 12 μm. A comparatively large value of D10 corresponds to a comparatively small amount of a fine powder (excessively fine phosphor particles in which the conversion efficiency of the blue light tends to decrease) in the phosphor powder. Therefore, the conversion efficiency of the blue light tends to increase, when D10 is a relatively large value.

From another viewpoint, a volume-based cumulative 90% particle size D90 of the phosphor powder of the present embodiment measured by the laser diffraction scattering method is preferably equal to or more than 15 μm and equal to or less than 50 μm and more preferably equal to or more than 18 μm and equal to or less than 40 μm. D90 that is not excessively large corresponds to a small amount of coarse particles in the phosphor powder. The phosphor powder having D90 that is not excessively large is effective in reducing the chromaticity variation of the light-emitting device.

In addition, in general, as a particle size of particles included in the powder increases, the effect of light scattering decreases and diffuse reflectance tends to decrease. In other words, a size of the particle and the diffuse reflectance are in a relationship of trade-off. However, although a preferred particle size (D50 or the like) of the phosphor powder of the present embodiment is comparatively large, the diffuse reflectance of the phosphor powder of the present embodiment tends to be comparatively large.

(Production Method) The phosphor powder of the present embodiment can be produced, for example, by a series of steps including the following (1) to (4), a series of steps including (1) to (3) and (5), or a series of steps including (1) to (5). From a viewpoint of suitably adjusting the diffuse reflectance of the phosphor powder, a production step of the phosphor powder preferably includes a (4) acid treatment step and/or (5) classification step (preferably a sedimentation classification).
(1) Preparation step of raw material mixed powder
(2) Firing step
(3) Pulverization step of fired product
(4) Acid treatment step
(5) Classification step (preferably sedimentation classification)
(1) to (5) will be specifically described below.

(1) Preparation Step of Raw Material Mixed Powder

In the preparation step of raw material mixed powder, a raw material mixed powder is normally obtained by mixing suitable raw material powders.

As the raw material powder, nitrides of constituent elements such as silicon nitride, aluminum nitride, lithium nitride, cerium nitride, and nitrides of alkaline earth elements (for example, calcium nitride) are preferably used. In general, a nitride powder is unstable in air, and the particle surface is covered with an oxide layer, and as a result, even in a case where the nitride raw material is used, a certain amount of oxide is contained in the raw material. In a case of controlling the O/N ratio of the phosphor, when these are considered and the amount of oxygen is insufficient, a portion of the nitride may be an oxide (including a compound that becomes an oxide by heat treatment). Examples of oxide can include cerium oxide and the like.

Among the raw material powders, a lithium compound is remarkably volatilized by heating, and most of them may be volatilized depending on a firing condition. Therefore, it is preferable to determine the amount of the lithium compound to be blended in consideration of the volatilization amount during a firing process according to the firing condition.

Among the nitride raw material powders, lithium nitride, cerium nitride, and nitride of the alkaline earth element react violently with moisture in the air. Therefore, it is preferable to carry out these handlings in a glove box substituted with an inert atmosphere.

From a viewpoint of work efficiency, it is preferable that, (i) first, predetermined amounts of the raw material powders of silicon nitride, aluminum nitride, and various oxides that can be handled in the air are weighed and thoroughly mixed in the air in advance to prepare a premixed powder, (ii) then, the premixed powder is mixed with a substance such as lithium nitride that reacts easily with moisture in a glove box to prepare a raw material mixed powder.

(2) Firing Step

In the firing step, the raw material mixed powder prepared in the (1) preparation step of raw material mixed powder is filled in a suitable container and heated using a firing furnace or the like. A firing temperature is preferably 1600° C. to 2000° C. and more preferably 1700° C. to 1900° C., from viewpoints of sufficiently proceeding the reaction and suppressing the volatilization of lithium.

A firing time is preferably 2 to 24 hours and more preferably 4 to 16 hours, from viewpoints of sufficiently proceeding the reaction and suppressing the volatilization of lithium.

The firing step is preferably performed in a nitrogen atmosphere. In addition, it is preferable to appropriately adjust a pressure of the firing atmosphere. Specifically, the pressure of the firing atmosphere is preferably equal to or more than 0.5 MPa·G. Particularly, in a case where the firing temperature is equal to or higher than 1800° C., the phosphor tends to be easily decomposed, but the high pressure of the firing atmosphere can suppress the decomposition of the phosphor.

Incidentally, considering industrial productivity, the pressure of the firing atmosphere is preferably less than 1 MPa·G.

It is preferable that the container filled with the raw material mixed powder is formed of a material that is stable in a high-temperature nitrogen atmosphere and does not react with the raw material mixed powder or a reaction product thereof. A material of the container is preferably boron nitride.

(3) Pulverization Step of Fired Product

Since a fired product obtained in (2) is usually in the form of a block, it is preferable to pulverize it to a somewhat small size by applying a mechanical force.

In the pulverization, various devices such as a crusher, a mortar, a ball mill, a vibration mill, a jet mill, and a stamp mill can be used. Two or more of these devices may be combined for the pulverization. In examples which will be described later, first, a stamp mill is used to obtain a coarsely pulverized product of the fired product, and then the coarsely pulverized product is further finely pulverized using a jet mill. Although the details are unknown, such pulverization facilitates obtaining a phosphor powder having a diffuse reflectance X1 of 88% or more and 99.9% or less.

(4) Acid Treatment Step

In the acid treatment step, for example, the pulverized product obtained in (3) above is immersed in an acid aqueous solution. Although the details are not clear, it is considered that the acid treatment removes or reduces “heterogeneous phases” in the phosphor that do not contribute to the light emission or that reduce the luminous efficiency. Incidentally, as described above, a value of the diffuse reflectance X1 of the phosphor powder that is equal to or more than 88% and equal to or less than 99.9% can correspond to removal or reduction of the heterogeneous phase.

Examples of the acid aqueous solution include an acid aqueous solution containing one acid selected from acids such as hydrofluoric acid, nitric acid, and hydrochloric acid, and a mixed acid aqueous solution obtained by mixing two or more of the above acids. The acid is preferably nitric acid or hydrochloric acid and more preferably hydrochloric acid.

A concentration of the acid aqueous solution is suitably set according to strength of the acid used, and is, for example, 0.5 to 50% by mass, preferably 1 to 30% by mass, and more preferably 1 to 10% by mass.

A temperature in a case of performing the acid treatment is preferably equal to or higher than 25° C. and equal to or lower than ° C. and more preferably equal to or higher than 60° C. and equal to or lower than 90° C. By performing the process at a comparatively high temperature, the phosphor powder having the diffuse reflectance X1 equal to or more than 88% and equal to or less than 99.9% is easily obtained.

A time of the acid treatment (an immersion time) is preferably equal to or more than 15 minutes and equal to or less than 80 minutes and more preferably equal to or more than 15 minutes and equal to or less than 60 minutes.

After the acid treatment, it is preferable to sufficiently wash the phosphor powder with water and dry it.

(5) Classification (Sedimentation Classification) Step

In order to reduce the amount of fine powder (extremely fine phosphor particles that tend to deteriorate the conversion efficiency of blue light) in the powder, it is preferable to perform a suitable classification treatment. In order to effectively remove the fine powder, a classification method is preferably sedimentation classification as described below.

First, typically, the powder obtained in (3) the pulverization step of the fired product or the powder obtained through (4) the acid treatment step is dispersed in a suitable liquid, for example, an aqueous solution of sodium hexametaphosphate in a container to obtain a dispersion.

Next, the dispersion is allowed to stand for a predetermined period of time to precipitate powders having comparatively large particle sizes among the powder in the dispersion.

After that, a supernatant is discharged.

Then, the operations of newly putting the aqueous solution of sodium hexametaphosphate into the container in which the sediment remains, dispersing the phosphor, allowing the mixture to stand, and discharging the supernatant are repeated multiple times. The “multiple times” is preferably equal to or more than 5 times. There is no particular upper limit to the number of times, but from a viewpoint of cost, it is, for example, equal to or less than 15 times, specifically equal to or less than 10 times.

By the classification, the amount of fine powder (extremely fine phosphor particles that tend to deteriorate the conversion efficiency of blue light) in the powder can be reduced. Incidentally, a value of the diffuse reflectance X1 of the phosphor powder that is equal to or more than 88% and equal to or less than 99.9% can correspond to a small amount of fine powder in the phosphor powder.

A specific condition for the classification is not particularly limited, as long as a phosphor powder having the diffuse reflectance X1 equal to or more than 88% and equal to or less than 99.9% can be finally obtained. The specific condition for the classification is only guideline, but the condition of the classification is preferably set so that a fine powder having a particle size equal to or less than 10 μm is removed, and the condition of the classification is preferably set so that a fine powder having a particle size equal to or less than 7.5 μm is removed. When setting the condition, in a case of the sedimentation classification, Stokes' equation for a sedimentation velocity of particles can be referred to.

<Light-Emitting Device, Image Display Device, and Illumination Device>

A light-emitting device can be obtained by combining the phosphor powder of the present embodiment and a light emitting source.

The light emitting source typically emits ultraviolet or visible light. For example, in a case where the light emitting source is a blue LED, the blue light emitted from the light emitting source irradiates the phosphor powder and the blue light is converted into light having a longer wavelength. That is, the phosphor powder of the present embodiment can be used as a wavelength conversion material that converts the blue light into light having a longer wavelength.

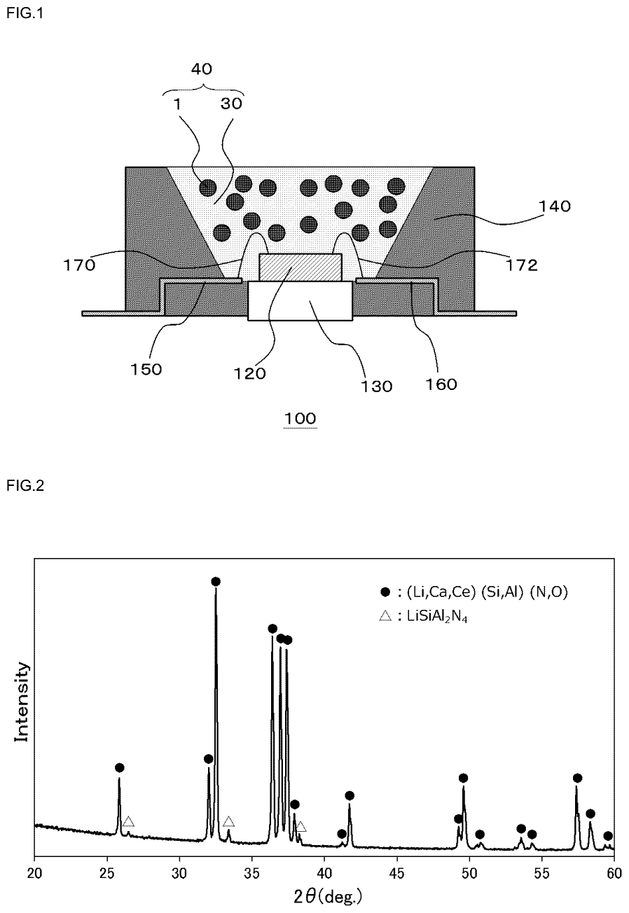

An example of a specific configuration of the light-emitting device will be described with reference to FIG. 1.

FIG. 1 is a schematic cross-sectional view showing an example of a structure of a light-emitting device. As shown in FIG. 1, a light-emitting device 100 includes a light-emitting element 120, a heat sink 130, a case 140, a first lead frame 150, a second lead frame 160, a bonding wire 170, a bonding wire 172, and a composite 40.

The light-emitting element 120 is mounted in a predetermined region on the upper surface of the heat sink 130. By mounting the light-emitting element 120 on the heat sink 130, the heat dissipation of the light-emitting element 120 can be enhanced. Further, a packaging substrate may be used instead of the heat sink 130.

The light-emitting element 120 is a semiconductor element that emits excitation light. As the light-emitting element 120, for example, an LED chip that generates light at a wavelength of equal to or more than 300 nm and equal to or less than 500 nm, corresponding to near-ultraviolet to blue light, can be used. One electrode (not shown in the drawings) arranged on the upper surface side of the light-emitting element 120 is connected to the surface of the first lead frame 150 through the bonding wire 170 such as a gold wire. In addition, the other electrode (not shown in the drawings) formed on the upper surface of the light-emitting element 120 is connected to the surface of the second lead frame 160 through the bonding wire 172 such as a gold wire.

In the case 140, a substantially funnel-shaped recess whose hole diameter gradually increases toward the upside from the bottom surface is formed. The light-emitting element 120 is provided on the bottom surface of the recess. The wall surface of the recess surrounding the light-emitting element 120 serves as a reflective plate.

The recess whose wall surface is formed by the case 140 is filled with the composite 40. The composite 40 is a wavelength conversion member that converts excitation light emitted from the light-emitting element 120 into light at a longer wavelength.

The composite 40 is obtained by dispersing at least the phosphor powder of the present embodiment in the sealing material 30 such as resin. In order to obtain white light of higher quality, the sealing material 30 may contain not only the phosphor powder of the present embodiment but also other phosphor powders.

The light-emitting device 100 emits a mixed color of light from the light-emitting element 120 and light emitted from the phosphor particles 1 excited by absorbing the light emitted from the light-emitting element 120. The light-emitting device 100 preferably emits white light by mixing the light from the light-emitting element 120 and the light generated from the phosphor particles 1.

Incidentally, FIG. 1 illustrates a surface-mounted type light-emitting device, but the light-emitting device is not limited to the surface-mounted type, and may be shell-type, chip-on-board (COB) type, or chip-scale package (CSP) type.

The light-emitting device is used in an image display device such as a display and an illumination device. For example, a liquid crystal display can be manufactured using the light-emitting device 100 as a backlight. In addition, the illumination device can be manufactured by performing suitable wiring using one or a plurality of the light-emitting devices 100.

The embodiments of the present invention have been described above, but these are examples of the present invention and various configurations other than the examples can also be adopted. In addition, the present invention is not limited to the above-described embodiment, and modifications, improvements, and the like within the range in which the object of the present invention can be achieved are included in the present invention.

### EXAMPLES

The embodiment of the present invention will be described in detail based on examples and comparative examples. It is noted, just to be sure, that the present invention is not limited to only Examples.

<Producing Phosphor Powder>

(Example 1)

(1) Preparation of Raw Material Mixed Powder

First, premixing was performed. Specifically, among the raw materials shown in Table 1, Si₃N₄, AIN, and CeO₂ were mixed (dry-blended) for 30 minutes using a small V-type mixer, and then sieved with a nylon sieve having an opening of 150 μm. A premixed powder was thus obtained.

Next, in a glove box of the nitrogen atmosphere, the remaining materials (Ca₃N₂ and Li₃N) of the raw materials shown in Table 1 were added to the premixed powder, thoroughly dry-blended, and then sieved with a sieve having an opening of 500 μm. A raw material mixed powder was thus obtained.

(2) Firing

A container formed of boron nitride was filled with the raw material mixed powder. This container was placed in a furnace, and the raw material mixed powder was fired at 1800° C. for 8 hours in a N₂ atmosphere of 0.72 MPa G.

(3) Pulverization of Fired Product

The fired product obtained in (2) was pulverized using a stamp mill. The pulverization by the stamp mill was repeated until a passing rate of a vibrating sieve having an opening of 250 μm exceeded 90%.

The fired product pulverized by the stamp mill was further pulverized by using a jet mill (manufactured by Nippon Pneumatic Industry, PJM-80SP). In pulverization conditions, a sample supply rate was set as 50 g/min and a pulverization air pressure was set as 0.3 MPa.

(4) Acid Treatment

The pulverized fired product was put into hydrochloric acid for acid treatment.

Specifically, first, 35 to 37% by mass of hydrochloric acid and distilled water were mixed at a volume ratio of 50 mL: 300 mL to prepare an aqueous solution of hydrochloric acid heated to 80° C. The fired product pulverized in (3) was added to this aqueous solution of hydrochloric acid and stirred for 0.5 hours for the acid treatment.

The acid-treated fired product was thoroughly washed with distilled water and then dried at 110° C. for 3 hours. Then, it was sieved with a sieve having an opening of 45 μm to remove coarse/aggregated particles.

(5) Removal of Fine Powder by Sedimentation Classification

First, an aqueous solution of 0.05% by mass sodium hexametaphosphate was prepared. Then, this aqueous solution was placed in a container having an inner diameter of 70 mm and a height of 120 mm up to a height of 110 mm.

Next, the acid-treated fired product was put into the container containing the above aqueous solution, thoroughly stirred and dispersed, and then allowed to stand still for 22 minutes. After standing still, a supernatant was discharged from the top by 90 mm. After that, the aqueous solution of sodium hexametaphosphate was added up to a height of 110 mm, and the powder was dispersed by stirring again, and the same treatment was performed. This operation was repeated 7 times to remove the fine powder contained in the acid-treated powder (incidentally, a classification point is 7.5 μm based on the Stokes' equation).

Then, a slurry at the bottom of the container was filtered while washing with water to collect a solid content, dried in a condition of 110° C. for 3 hours, and sieved with a sieve having an opening of μm to crush aggregated particles.

From the above, the phosphor powder was obtained.

### Example 2

A phosphor powder was obtained in the same manner as in Example 1, except that the sedimentation classification was not performed.

### Example 3

A phosphor powder was obtained in the same manner as in Example 1, except that (a) a material shown in Table 1 was used as the raw material, (b) the acid treatment was not performed (a fired product pulverized with a jet mill was provided for the sedimentation classification without the acid treatment), and (c) a pulverization air pressure in the jet mill pulverization was set as 0.6 MPa.

### Example 4

A phosphor powder was obtained in the same manner as in Example 1, except that (a) a material shown in Table 1 was used as the raw material and (b) the sedimentation classification was not performed.

### Example 5

A phosphor powder was obtained in the same manner as in Example 4, except that nitric acid having a concentration of 60% by mass was used instead of hydrochloric acid in the acid treatment.

### Example 6

A phosphor powder was obtained in the same manner as in Example 1, except that (a) a material shown in Table 1 was used as the raw material and (b) the acid treatment was not performed (a fired product pulverized with a jet mill was provided for the sedimentation classification without the acid treatment).

### Comparative Example 1

A phosphor powder was obtained in the same manner as in Example 4, except that (a) a material shown in Table 1 was used as the raw material and (b) the acid treatment was not performed.

### Example 7

A phosphor powder was obtained in the same manner as in Example 1, except that (a) a material shown in Table 1 was used as the raw material, (b) the acid treatment was not performed (a fired product pulverized with a jet mill was provided for the sedimentation classification without the acid treatment), and (c) the fired product pulverized with the jet mill was provided for the sedimentation classification after being sieved through a sieve having an opening of 45 μm to remove coarse/aggregated particles.

### Example 8

A phosphor powder was obtained in the same manner as in Example 1, except that (a) a material shown in Table 1 was used as the raw material, (b) the acid treatment was not performed (a fired product pulverized with a jet mill was provided for the sedimentation classification without the acid treatment), (c) a pulverization air pressure in the jet mill pulverization was set as 0.4 MPa, and (d) the fired product pulverized with the jet mill was provided for the sedimentation classification after being sieved through a sieve having an opening of 45 μm to remove coarse/aggregated particles.

<Confirmation of Chemical Composition/Crystal Structure>

Some phosphor powders were analyzed for composition as follows.

Amounts of Ca, Li, Ce, Si, and Al: the phosphor powder was dissolved by an alkali fusion method, and then the amounts thereof were measured with an ICP emission spectrometer (CIROS-120 manufactured by Rigaku Co., Ltd.).

Amount of 0 and N: Measured with an Oxygen Nitrogen Analyzer (Manufactured by HORIBA, EMGA-920).

Based on the measurement results, x, y, the Si/Al atomic ratio, the O/N atomic ratio, the Li ratio of M, and the Ce ratio of M in the general formula Mₓ(Si, Al)₂(N, O)_{3±y} were obtained.

In addition, the phosphor powder was dissolved with a mixed acid of hydrofluoric acid and nitric acid by a pressure acid decomposition method, and then, the contents of the Cr element, and the Fe element which are impurities were measured by an ICP emission spectrometer.

The phosphor of Example 1 was also subjected to powder X-ray diffraction (XRD) measurement using Cu-Kα rays using an X-ray diffractometer (Ultima IV-N manufactured by Rigaku Co., Ltd.). The obtained XRD pattern is shown in FIG. 2. From the analysis of the obtained XRD pattern, crystals with lattice constants of a=0.9486 nm, b=0.5586 nm, and c=0.4933 nm as orthorhombic crystal were confirmed as a main phase and a small amount of LiAlSi₂N₄ was confirmed as the heterogeneous phase.

Incidentally, the chemical compositions of the phosphor powders of Examples 4 and 5 are substantially unmeasured. However, the production step up to the pulverization of the fired product is the same in Example 3 and Examples 4 and 5, and the composition of the raw material mixed powder in Examples 4 and 5 is the same as in Example 3. In addition, although the production procedure differs between Example 3 and Examples 4 and 5, it is difficult to believe that a difference thereof has a great effect on the chemical composition. Therefore, the measurement of the chemical composition of the phosphor powders of Examples 4 and 5 was not described repeatedly.

In the same manner, the chemical composition of the phosphor powder of Example 8 is similar to that of Example 7. In addition, although the production procedure differs between Examples 7 and 8, it is difficult to believe that a difference thereof has a great effect on the chemical composition. Therefore, the measurement of the chemical composition of the phosphor powder of Example 8 was not described repeatedly.

<Measurement of Diffuse Reflectance>

The diffuse reflectance was measured using a device in which an integrating sphere device (ISV-469) is attached to an ultraviolet and visible spectrophotometer (V-550) manufactured by JASCO

Corporation. At the time of the measurement, baseline correction was performed using a standard reflective plate (Spectralon).

A solid sample holder filled with the phosphor powder was attached to a predetermined position in the device, a diffuse reflectance spectrum was measured in a wavelength range of 500 to 850 nm, and diffuse reflectance of the phosphor powder with respect to light having a wavelength of 700 nm and light having a fluorescence peak wavelength (which will be described later) were obtained.

<Measurement of Particle Size Distribution>

The particle size distribution was measured by a laser diffraction scattering method based on JIS R 1629:1997 using LS13 320 (manufactured by Beckman Coulter, Inc.). Water was used as a measurement solvent.

As a specific procedure, first, a small amount of phosphor powder was added to an aqueous solution containing 0.05% by mass of sodium hexametaphosphate as a dispersant. Next, dispersion treatment was performed with a horn-type ultrasonic homogenizer (output of 300 W, horn diameter of 26 mm) to prepare a dispersion. A suitable amount of this dispersion was added to the measurement solvent, and the particle size distribution was measured. A 10% particle volume size D₁₀, a 50% volume particle size D₅₀, and a 90% particle volume size D₉₀ were obtained from the obtained cumulative volume frequency distribution curve.

<Evaluation>

(Fluorescence Peak Intensity)

A fluorescence spectrum of the phosphor powder was measured using a fluorescent spectrophotometer (F-7000, manufactured by Hitachi High-Tech Science Co., Ltd.) corrected with Rhodamine B and a secondary standard light source. Specifically, the fluorescence spectrum emitted by exciting the phosphor powder with monochromatic light having a wavelength of 455 nm was measured, and the fluorescence peak intensity and fluorescence peak wavelength were determined.

The fluorescence peak intensity varies depending on the measuring device and conditions. The fluorescence peak intensity described in the table below is a value in a case where the fluorescence peak intensity of a standard sample (YAG, more specifically P46Y3 manufactured by Mitsubishi Chemical Corporation) is set to 100.

(Internal Quantum Efficiency and External Quantum Efficiency)

Using a spectrophotometer (MCPD-7000 manufactured by Otsuka Electronics Co., Ltd.), internal quantum efficiency and external quantum efficiency of each phosphor powder were obtained by the following procedure.

(1) The phosphor powder was filled into a recessed part of a recessed cell to have a smooth surface. This recessed cell was attached to a predetermined position (a sample part) within an integrating sphere. Monochromatic light spectrally split into a wavelength of 455 nm from a light emitting source (Xe lamp) was introduced into the integrating sphere using an optical fiber. This monochromatic light (excitation light) was emitted to the phosphor powder filled in the recessed part of the recessed cell, and the fluorescence spectrum was measured. From the spectral data obtained, a peak wavelength was determined, and the number of excitation reflected light photons (Qref) and the number of fluorescence photons (Qem) were calculated. The number of excitation reflected light photons was calculated in a wavelength range of equal to or more than 450 nm and equal to or less than 465 nm, and the number of fluorescence photons was calculated in a wavelength range of equal to or more than 465 nm and equal to or less than 800 nm.

(2) Next, instead of the recessed cell, a standard reflective plate (Spectralon manufactured by Labsphere) having a reflectance of 99% was attached to the sample part, and a spectrum of the excitation light at a wavelength of 455 nm was measured. Then, the number of excitation light photons (Qex) was calculated from the spectrum in a wavelength range of equal to or more than 450 nm and equal to or less than 465 nm.

(3) From the Qref, Qem, and Qex obtained in (1) and (2) above, the internal quantum efficiency and the external quantum efficiency were calculated based on the following equations.

Internal quantum efficiency=(Qem/(Qex−Qref))×100 External quantum efficiency=(Qem/Qex)×100

Various pieces of information are collectively shown in Table 1.

In Table 1, “N.D.” stands for Not Detected.

In addition, in Table 1, each raw material described in a column of “raw materials used” is as follows.

Ca₃N₂-1: Ca₃N₂ manufactured by Taiheiyo Cement Co., Ltd.

Ca₃N₂-2: Ca₃N₂ manufactured by CERAC (currently Materion)

Li₃N from Materion

Li₃N manufactured by CERAC (currently Materion)

Li₃N-3: Li₃N manufactured by Kojundo Chemical Laboratory Co., Ltd.

CeO₂-1: CeO₂, C grade manufactured by Shin-Etsu Chemical Co., Ltd.

Si₃N₄-1: Si₃N₄ manufactured by Ube Industries, E10 grade

AlN-1: AIN manufactured by Tokuyama Corporation, E grade

TABLE 1

| Example/ | | Example | Example | Example | Example | Example | Example | Comparative | Example | Example |
|---|---|---|---|---|---|---|---|---|---|---|
| Comparative Example | | 1 | 2 | 3 | 4 | 5 | 6 | Example 1 | 7 | 8 |
| Raw | Ca₃N₂ | 19.528 | 19.528 | 19.528 | 19.528 | 19.528 | 19.528 | 19.528 | 20.28 | 16.55 |
| material | Li₃N | 3.900 | 3.900 | 3.900 | 3.900 | 3.900 | 3.900 | 3.900 | 4.05 | 4.96 |
| (% by | CeO₂ | 3.345 | 3.345 | 3.345 | 3.345 | 3.345 | 3.345 | 3.345 | 0.85 | 1.46 |
| mass) | Si₃N₄ | 55.437 | 55.437 | 55.437 | 55.437 | 55.437 | 55.437 | 55.437 | 57.58 | 62.63 |
| | AIN | 17.791 | 17.791 | 17.791 | 17.791 | 17.791 | 17.791 | 17.791 | 17.23 | 14.42 |
| Raw | Ca₃N₂-2 | Ca₃N₂-2 | Ca₃N₂-2 | Ca₃N₂-2 | Ca₃N₂-2 | Ca₃N₂-2 | Ca₃N₂-2 | Ca₃N₂-2 | Ca₃N₂-2 | Ca₃N₂-2 |
| material | Li₃N-3 | Li₃N-3 | Li₃N-3 | Li₃N-3 | Li₃N-3 | Li₃N-3 | Li₃N-3 | Li₃N-3 | Li₃N-3 | Li₃N-3 |
| used | CeO₂-1 | CeO₂-1 | CeO₂-1 | CeO₂-1 | CeO₂-1 | CeO₂-1 | CeO₂-1 | CeO₂-1 | CeO₂-1 | CeO₂-1 |
| | Si₃N₄-1 | Si₃N₄-1 | Si₃N₄-1 | Si₃N₄-1 | Si₃N₄-1 | Si₃N₄-1 | Si₃N₄-1 | Si₃N₄-1 | Si₃N₄-1 | Si₃N₄-1 |
| | AlN-1 | AlN-1 | AlN-1 | AlN-1 | AlN-1 | AlN-1 | AlN-1 | AlN-1 | AlN-1 | AlN-1 |
| Chemical | x | 0.78 | 0.76 | 0.84 | Un- | Un- | 0.83 | 0.84 | 0.78 | Un- |
| composition | | | | | measured | measured | | | | measured |
| | y | 0.33 | 0.34 | 0.14 | Un- | Un- | 0.20 | 0.34 | 0.10 | Un- |
| | | | | | measured | measured | | | | measured |
| | Si/Al | 2.49 | 2.46 | 2.72 | Un- | Un- | 2.70 | 2.72 | 3.07 | Un- |
| | | | | | measured | measured | | | | measured |
| | O/N | 0.04 | 0.05 | 0.05 | Un- | 0.05 | 0.05 | 0.05 | 0.03 | Un- |
| | | | | | measured | | | | | measured |
| | Li/M (mol %) | 32.39 | 30.43 | 39.40 | Un- | Un- | 40.31 | 40.45 | 36.09 | Un- |
| | | | | | measured | measured | | | | measured |
| | Ce/M (mol %) | 2.87 | 3.02 | 2.73 | Un- | Un- | 2.72 | 2.73 | 0.73 | Un- |
| | | | | | measured | measured | | | | measured |
| Impurities | Cr | N.D. | N.D. | Un- | N.D. | <3 | N.D. | 3.1 | Un- | Un- |
| (ppm) | | | | measured | | | | | measured | measured |
| | Fe | 6.6 | 7.3 | Un- | 6.4 | 10.8 | 6.5 | 17.4 | Un- | Un- |
| | | | | measured | | | | | measured | measured |
| Diffuse | X1 (λ = | 96.7 | 95.8 | 94.2 | 93.9 | 91.5 | 90.5 | 87.5 | 95.5 | 94.3 |
| reflectance | 700 nm) | | | | | | | | | |
| (%) | X2 (λ = peak | Un- | Un- | 88.5 | 88.7 | 86.7 | 85.6 | 83.8 | 91.5 | 89.4 |
| | wavelength) | measured | measured | | | | | | | |
| | x1 − x2 | — | — | 5.6 | 5.2 | 4.8 | 4.8 | 3.8 | 4.0 | 4.9 |
| Particle | D₁₀ (μm) | 9.9 | 6.0 | 9.3 | Un- | Un- | 9.7 | 6.4 | 10.2 | 8.8 |
| size | | | | | measured | measured | | | | |
| distribution | D₅₀ (μm) | 16.2 | 14.7 | 13.8 | Un- | Un- | 15.2 | 13.9 | 19.7 | 13.5 |
| | | | | | measured | measured | | | | |
| | D₉₀ (μm) | 25.0 | 24.5 | 20.2 | Un- | Un- | 24.0 | 23.0 | 35.0 | 21.5 |
| | | | | | measured | measured | | | | |

| | | | | | | | | | |
|---|---|---|---|---|---|---|---|---|---|
| Fluorescence peak | 595.8 | 600.3 | 596.3 | 601.0 | 598.5 | 598.5 | 595.3 | 575.8 | 579.5 |
| wavelength (nm) | | | | | | | | | |
| Special feature related | Including | Including | Including | Including | Including | Including | — | Including | Including |
| to production method | hydrochloric | hydrochloric | sedimen- | hydro- | nitric acid | sedimen- | | sedimen- | sedimen- |
| | acid | acid | tation | chloric | treatment | tation | | tation | tation |
| | treatment and | treatment | classi- | acid | | classi- | | classi- | classi- |
| | sedimentation | | fication | treatment | | fication | | fication | fication |
| | classification | | | | | | | | |
| Relative fluorescence | 126.3 | 118.6 | 111.5 | 108.0 | 104.3 | 108.8 | 100.9 | 96.3 | 99.6 |
| peak intensity (455 nm, | | | | | | | | | |
| P46Y3 ratio) | | | | | | | | | |
| Internal quantum | 80.9% | 80.0% | 77.1% | 79.1% | 76.2% | 75.3% | 71.9% | 84.1% | 81.0% |
| efficiency | | | | | | | | | |
| External quantum | 70.9% | 65.8% | 67.7% | 68.5% | 64.6% | 67.1% | 62.6% | 60.3% | 63.8% |
| efficiency | | | | | | | | | |

As shown in Table 1, the phosphor powder (Examples 1 to 8) including the phosphor particles represented by the general formula Mₓ(Si, Al)₂(N, O)_{3±y} and having the diffuse reflectance X1 equal to or more than 88% and equal to or less than 99.9% exhibited excellent fluorescence peak intensity, internal quantum efficiency, and external quantum efficiency.

On the other hand, the phosphor powder (Comparative Example 1) having the diffuse reflectance X1 less than 88% was inferior to Examples 1 to 8 at least in the internal quantum efficiency.

This application claims priority based on Japanese Patent Application No. 2020-189203 filed on Nov. 13, 2020, the disclosure of which is incorporated herein by reference in its entirety.

### REFERENCE SIGNS LIST

1 phosphor particles
30 sealing material
40 composite
100 light-emitting device
120 light-emitting element
130 heat sink
140 case
150 first lead frame
160 second lead frame
170 bonding wire
172 bonding wire

1. A phosphor powder which is represented by a general formula Mₓ(Si, Al)₂(N, O)_{3±y}, (where M is Li and one or more alkaline earth metal elements and 0.52≤x≤0.9 and 0.06≤y≤0.36 are satisfied) and in which a part of M is substituted with a Ce element,
wherein the phosphor powder includes phosphor particles in which a Si/Al atomic ratio is equal to or more than 1.5 and equal to or less than 6,
an O/N atomic ratio is equal to or more than 0 and equal to or less than 0.1,
5 to 50 mol % of M is Li, and
0.5 to 10 mol % of M is Ce, and
a diffuse reflectance X1 with respect to light having a wavelength of 700 nm is equal to or more than 88% and equal to or less than 99.9%.

2. The phosphor powder according to claim 1,
wherein a diffuse reflectance X2 of the phosphor powder with respect to light having a fluorescence peak wavelength is equal to or more than 85% and equal to or less than 95%.

3. The phosphor powder according to claim 1,
wherein a difference X1-X2 between the diffuse reflectance X1 with respect to the light having the wavelength of 700 nm and the diffuse reflectance X2 with respect to light having the fluorescence peak wavelength is equal to or more than 4% and equal to or less than 8%.

4. The phosphor powder according to claim 1,
wherein a volume-based cumulative 50% size D₅₀ measured by a laser diffraction scattering method is equal to or more than 8 μm and equal to or less than 25 μm.

5. A light-emitting device comprising:
the phosphor powder according to claim 1; and
a light emitting source.

6. The light-emitting device according to claim 5,
wherein the light emitting source emits ultraviolet light or visible light.

7. An image display device comprising:
the light-emitting device according to claim 5.

8. An illumination device comprising:
the light-emitting device according to claim 5.
